(19) United States
(12) Patent Application Publication
(10) Pub. No.: US 2004/0135706 A1
(43) Pub. Date: Jul. 15, 2004

(54) Encoder attached with a roller

(76) Inventor: Chiu-Chieh Liu, Taichung (TW)

Correspondence Address: Chiu-Chieh Liu, 58, MA YUAN WEST ST., TAICHUNG, TW

(21) Appl. No.: 10/341,064

(22) Filed: Jan. 10, 2003

(51) Int. Cl. H03M 11/00; H03K 17/94

(52) U.S. Cl. 341/20

(57) ABSTRACT

An encoder includes a support rack, a main body, a switch contact plate, a swivel seat, a roller, a switch, a folding plate, and an elastic plate. Thus, the encoder has a reduced volume. In addition, the encoder has a simplified construction. Further, the encoder can reduce cost of fabrication.

### BACKGROUND OF THE INVENTION

1. Field of the Invention

The present invention relates to an encoder attached with a roller, and more particularly to an encoder attached with a roller, wherein the encoder has a reduced volume, has a simplified construction and can reduce cost of fabrication.

2. Description of the Related Art

A conventional encoder attached with a roller in accordance with the prior art shown in FIG. 1 comprises an encoder member A, a roller B, a roller positioning plate C, a switch D, a base plate E, and a press shaft F. When the roller B is rotated, the folding members (not shown) in the encoder member A will contact the contact plates (not shown) in an intermittent manner, thereby outputting a signal. In operation, the roller B is pressed, so that the roller B and the press shaft F are pressed downward, and the distal end of the press shaft F contacts the switch D, thereby forming the opened or closed state. However, the switch D is extended outward from one side of the encoder, thereby increasing the whole volume of the conventional encoder. In addition, the conventional encoder has a complicated construction with many parts. Further, the conventional encoder has higher cost of fabrication.

### SUMMARY OF THE INVENTION

The present invention is to mitigate and/or obviate the disadvantage of the conventional encoder attached with a roller.

The primary objective of the present invention is to provide an encoder attached with a roller, wherein the encoder has a reduced volume.

Another objective of the present invention is to provide an encoder attached with a roller, wherein the encoder has a simplified construction.

A further objective of the present invention is to provide an encoder attached with a roller, wherein the encoder can reduce cost of fabrication.

In accordance with the present invention, there is provided an encoder attached with a roller, comprising a support rack, a main body, a switch contact plate, a swivel seat, a roller, a switch, a folding plate, and an elastic plate, wherein:

the main body is mounted on the support rack and is formed with a plurality of encoder contact plates and a switch circuit, the switch circuit of the main body is formed with a switch socket for receiving the switch circuit;

the switch contact plate is mounted in the switch socket of the main body and is capable of contacting the switch circuit;

the swivel seat is mounted on the support rack and has a first side provided with a rotation shaft;

the roller is mounted on the rotation shaft of the swivel seat;

the switch is mounted on the support rack and has a first end formed with a push portion rested on the switch contact plate and a second end formed with a support portion rested on the roller; and

the folding plate is mounted on a second side of the swivel seat to rotate therewith, and is formed with a plurality of oblique folding portions contacting the encoder contact plates of the main body.

Further benefits and advantages of the present invention will become apparent after a careful reading of the detailed description with appropriate reference to the accompanying drawings.

### BRIEF DESCRIPTION OF THE DRAWINGS

FIG. 1 is a perspective view of a conventional encoder attached with a roller in accordance with the prior art.

FIG. 2 is a perspective view of an encoder attached with a roller in accordance with the preferred embodiment of the present invention;

FIG. 3 is a perspective view of an encoder attached with a roller in accordance with another embodiment of the present invention;

FIG. 4 is an exploded perspective view of the encoder attached with a roller in accordance with the present invention;

FIG. 5 is an ekploded perspective view of the encoder attached with a roller in accordance with the present invention;

FIG. 6 is a side plan cross-sectional assembly view of the encoder attached with a roller as shown in FIG. 3; and

FIG. 7 is a schematic operational view of the encoder attached with a roller as shown in FIG. 6 in use.

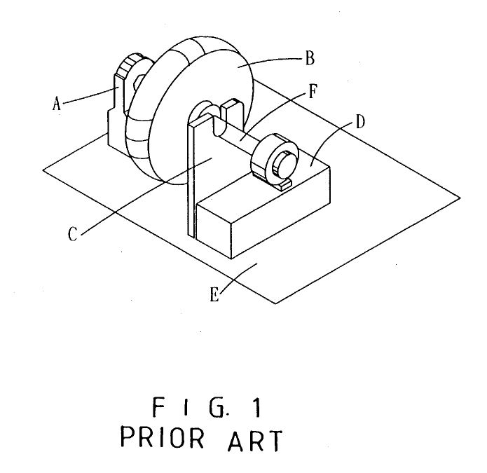

### DETAILED DESCRIPTION OF THE INVENTION

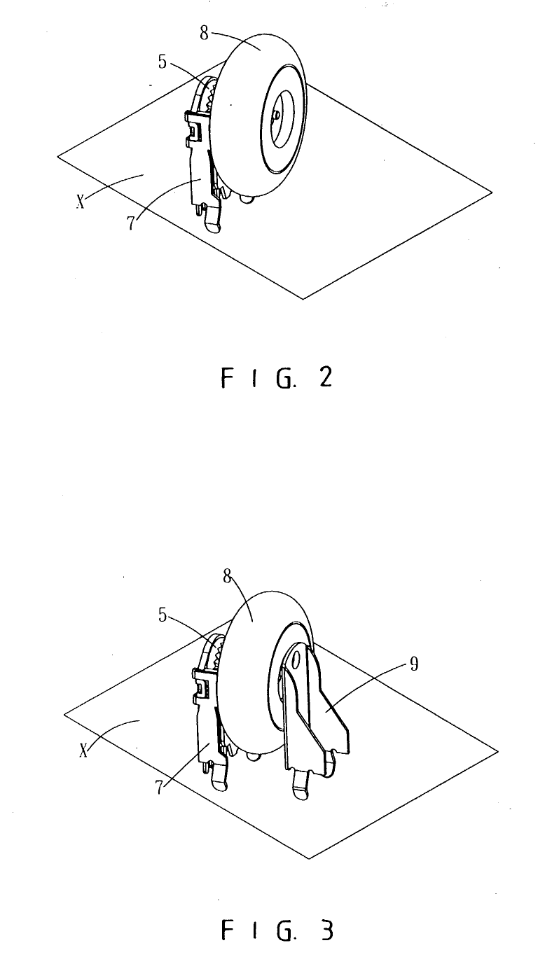

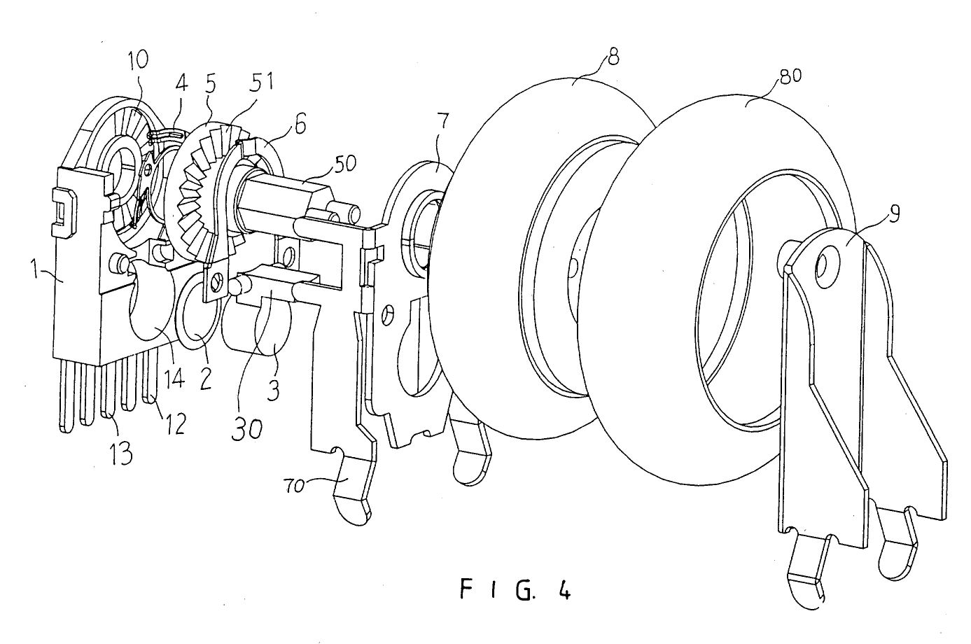

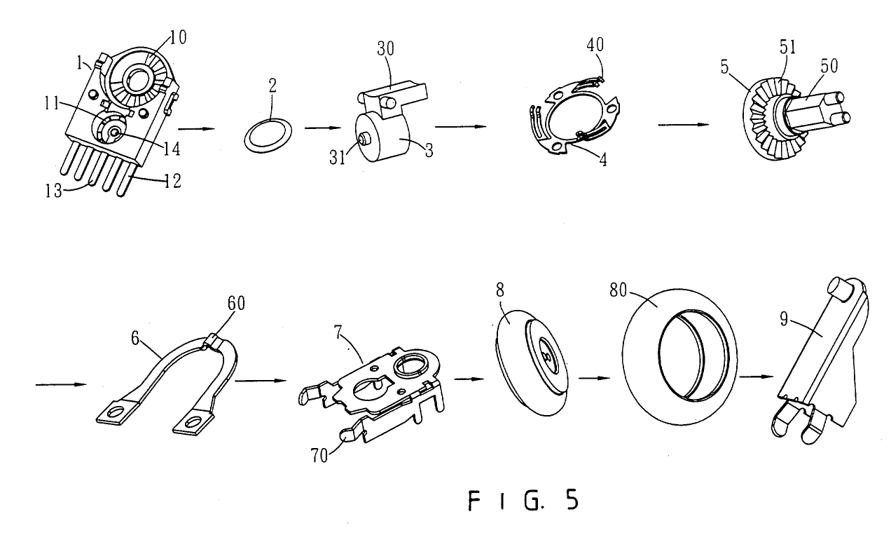

Referring to the drawings and initially to FIGS. 2-5, an encoder attached with a roller in accordance with the preferred embodiment of the present invention comprises a support rack 7, a main body 1, a switch contact plate 2, a swivel seat 5, a roller 8, a switch 3, a folding plate 4, and an elastic plate 6.

The support rack 7 is mounted on a base plate X, and is provided with two positioning portions 70 for securing the support rack 7 on the base plate X.

The main body 1 is mounted on the support rack 7. The main body 1 is formed with a plurality of encoder contact plates 10 and a switch circuit 11 by a punching process. The main body 1 is provided with a plurality of encoder signal output terminals 12 connected to the encoder contact plates 10 and a plurality of switch circuit output terminals 13 connected to the switch circuit 11. The switch circuit 11 of the main body 1 is formed with a switch socket 14 for receiving the switch circuit 11.

The switch contact plate 2 is mounted in the switch socket 14 of the main body 1.

The swivel seat 5 is mounted on the support rack 7. The swivel seat 5 has a first side provided with a rotation shaft 50. The first side of the swivel seat 5 has a periphery formed with a plurality of toothed portions 52.

The roller 8 is mounted on the rotation shaft 50 of the swivel seat 5. The encoder further comprises a soft sleeve 80 mounted on the roller 8.

The switch 3 is mounted on the support rack 7 and located under the swivel seat. The switch 3 has a first end formed with a push portion 31 rested on the switch contact plate 2 and a second end formed with a support portion 30 rested on the roller 8.

The folding plate 4 is mounted on a second side of the swivel seat 5 to rotate therewith. The folding plate 4 is formed with a plurality of oblique folding portions 40 contacting the encoder contact plates 10 of the main body 1.

The elastic plate 6 is mounted on the main body 1 and located between the swivel seat 5 and the support rack 7. The elastic plate 6 is formed with a locking portion 60 engaged with the toothed portions 52 of the swivel seat 5.

The encoder further comprises an auxiliary fixing rack 9 mounted on the base plate X, for supporting the roller 8.

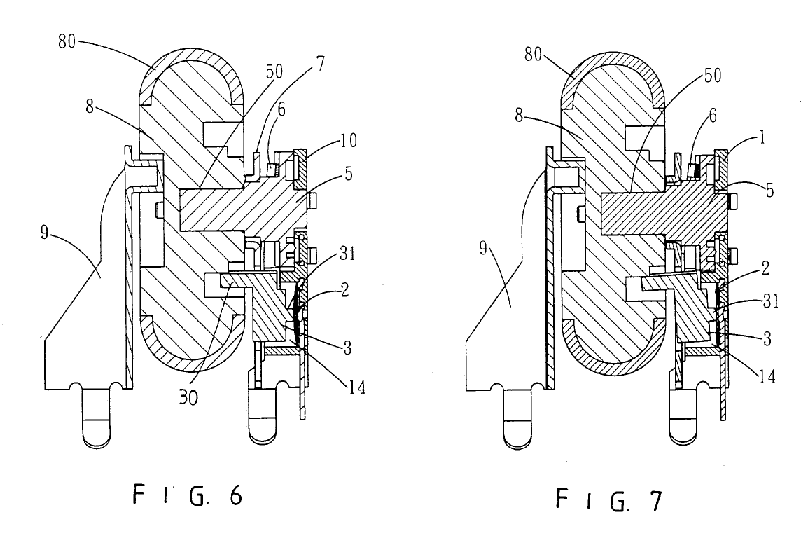

In operation, referring to FIGS. 6 and 7 with reference to FIGS. 2-5, the roller 8 is rotated to rotate the folding plate 4, so that the folding portions 40 the folding plate 4 contact the encoder contact plates 10 of the main body 1 in an intermittent manner. Thus, a signal is output by the time differential (and angle differential) between the time in which the folding portions 40 the folding plate 4 contact the encoder contact plates 10 of the main body 1 and the time in which the folding portions 40 the folding plate 4 do not contact the encoder contact plates 10 of the main body 1. The manner for outputting the signal is conventional and will not be further described in detail.

The roller 8 can be pressed toward the switch 30 to press the support portion 30 of the switch 3, so that the push portion 31 of the switch 3 is pressed to push the switch contact plate 2 to contact the switch circuit 11 in the switch socket 14 of the main body 1, thereby forming an opened state. Alternatively, after the roller 8 is released, the switch contact plate 2 is detached from the switch circuit 11 in the switch socket 14 of the main body 1 by the restoring force of the elastic plate 6, thereby forming a closed state.

Accordingly, the encoder has a reduced volume. In addition, the encoder has a simplified construction. Further, the encoder can reduce cost of fabrication.

Although the invention has been explained in relation to its preferred embodiment(s) as mentioned above, it is to be understood that many other possible modifications and variations can be made without departing from the scope of the present invention. It is, therefore, contemplated that the appended claim or claims will cover such modifications and variations that fall within the true scope of the invention.

What is claimed is:

1. An encoder attached with a roller, comprising a support rack, a main body, a switch contact plate, a swivel seat, a roller, a switch, a folding plate, and an elastic plate, wherein:
the main body is mounted on the support rack and is formed with a plurality of encoder contact plates and a switch circuit, the switch circuit of the main body is formed with a switch socket for receiving the switch circuit;
the switch contact plate is mounted in the switch socket of the main body and is capable of contacting the switch circuit;
the swivel seat is mounted on the support rack and has a first side provided with a rotation shaft;
the roller is mounted on the rotation shaft of the swivel seat;
the switch is mounted on the support rack and has a first end formed with a push portion rested on the switch contact plate and a second end formed with a support portion rested on the roller; and
the folding plate is mounted on a second side of the swivel seat to rotate therewith, and is formed with a plurality of oblique folding portions contacting the encoder contact plates of the main body.

2. The encoder attached with a roller in accordance with claim 1, wherein the support rack is mounted on a base plate.

3. The encoder attached with a roller in accordance with claim 2, wherein the support rack is provided with two positioning portions for securing the support rack on the base plate.

4. The encoder attached with a roller in accordance with claim 1, wherein the main body is provided with a plurality of encoder signal output terminals connected to the encoder contact plates.

5. The encoder attached with a roller in accordance with claim 1, wherein the main body is provided with a plurality of switch circuit output terminals connected to the switch circuit.

6. The encoder attached with a roller in accordance with claim 1, wherein the first side of the swivel seat has a periphery formed with a plurality of toothed portions, and the elastic plate is formed with a locking portion engaged with the toothed portions of the swivel seat.

7. The encoder attached with a roller in accordance with claim 1, further comprising a soft sleeve mounted on the roller.

8. The encoder attached with a roller in accordance with claim 1, wherein the elastic plate is mounted on the main body and located between the swivel seat and the support rack.

9. The encoder attached with a roller in accordance with claim 1, further comprising an auxiliary fixing rack for supporting the roller.

10. The encoder attached with a roller in accordance with claim 2, further comprising an auxiliary fixing rack mounted on the base plate, for supporting the roller.

11. The encoder attached with a roller in accordance with claim 1, wherein the switch is located under the swivel seat.
